(19) United States
(12) Patent Application Publication
(10) Pub. No.: US 2024/0079228 A1
(43) Pub. Date: Mar. 7, 2024

(54) LOW LOSS SILICON NITRIDE AND WAVEGUIDES COMPRISING LOW LOSS SILICON NITRIDE

(71) Applicant: Quantinuum LLC, Broomfield, CO (US)

(72) Inventors: Christopher John Carron, Broomfield, CO (US); Molly Krogstad, Westminster, CO (US); Robert Horning, Lakeville, MN (US); Robert Higashi, Broomfield, CO (US); David Deen, Broomfield, CO (US)

(21) Appl. No.: 18/456,872

(22) Filed: Aug. 28, 2023

Related U.S. Application Data
(60) Provisional application No. 63/374,412, filed on Sep. 2, 2022.

(51) Int. Cl. H01L 21/02

(52) U.S. Cl. CPC H01L 21/02219; H01L 21/0217; H01L 21/02274; G02B 6/1225

(57) ABSTRACT

A low loss silicon nitride film is formed by depositing a silicon nitride film on a substrate and annealing the silicon nitride film for at least ten hours at a temperature of at least 400° C. to cause the silicon nitride film to become a low loss silicon nitride film. The low loss silicon nitride film has an optical loss of less than 1 dB per cm at a wavelength of 488 nm.

### CROSS-REFERENCE TO RELATED APPLICATIONS

This application claims priority to U.S. Application No. 63/374,412, filed Sep. 2, 2022, the content of which is incorporated by reference herein in its entirety.

### TECHNICAL FIELD

Various embodiments relate to silicon nitride exhibiting low optical losses, including low optical losses a ultraviolet wavelengths For example, various embodiments relate to a low optical loss waveguide configured for guiding visible and/or ultraviolet light comprising a low loss silicon nitride waveguide core.

### BACKGROUND

Waveguides are used to direct optical signals from an optical source (e.g., a laser) to a target location. However, optical power loss as an optical signal propagates through a waveguide can reduce the ability of the waveguide to provide the optical signal. Through applied effort, ingenuity, and innovation many deficiencies of such waveguides have been solved by developing solutions that are structured in accordance with the embodiments of the present invention, many examples of which are described in detail herein.

### BRIEF SUMMARY OF EXAMPLE EMBODIMENTS

Example embodiments provide silicon nitride films and waveguide cores that have low optical losses, even at visible and ultraviolet wavelengths. For example, various embodiments provide low loss silicon nitride films, low loss silicon nitride waveguide cores, waveguides comprising low loss silicon nitride waveguide cores, and/or integrated photonic circuits comprising waveguides comprising low loss silicon nitride waveguide cores where the low loss silicon nitride exhibits optical losses of less than 1 dB per centimeter at 488 nm. Various embodiments provide methods for fabricating such low loss silicon nitride films, low loss silicon nitride waveguide cores, waveguides comprising low loss silicon nitride waveguide cores, and/or integrated photonic circuits comprising waveguides comprising low loss silicon nitride waveguide cores.

According to one aspect of the present disclosure, a method for forming a low loss silicon nitride film and/or a component comprising low loss silicon nitride is provided. In an example embodiment, the method comprises depositing a silicon nitride film on a substrate; and annealing the silicon nitride film for at least ten hours at a temperature of at least 400° C. to cause the silicon nitride film to become a low loss silicon nitride film. The low loss silicon nitride film has an optical loss of less than 1 dB per cm at a wavelength of 488 nm.

In an example embodiment, the silicon nitride film is formed using chemical vapor deposition.

In an example embodiment, the chemical vapor deposition is a plasma enhanced chemical vapor deposition (PECVD).

In an example embodiment, the PECVD is a low frequency (LF) PECVD.

In an example embodiment, the annealing is performed for at least twenty-four hours.

In an example embodiment, the annealing is performed for at least ninety hours.

In an example embodiment, the method further comprises at least one of (a) before depositing the silicon nitride film or (b) after depositing the silicon nitride film, forming at least one of (i) one or more electrical circuit components or (ii) optical circuit components on the substrate.

In an example embodiment, the method further comprises patterning the low loss silicon nitride film into a waveguide core.

In an example embodiment, the method further comprises depositing a cladding on the low loss silicon nitride film.

In an example embodiment, the waveguide core is a core of a waveguide configured for guiding at least one of visible or ultraviolet light.

According to another aspect, a waveguide for guiding visible and/or ultraviolet light is provided. In an example embodiment, the waveguide comprises a low loss silicon nitride waveguide core. The low loss silicon nitride waveguide core has an optical loss of less than 1 dB per cm at a wavelength of 488 nm.

In an example embodiment, the low loss silicon nitride waveguide core is formed by annealing a silicon nitride film for at least ten hours at a temperature of at least 400° C.

In an example embodiment, the silicon nitride film was formed by depositing the silicon nitride film on a substrate using chemical vapor deposition.

In an example embodiment, the chemical vapor deposition is a plasma enhanced chemical vapor deposition (PECVD).

In an example embodiment, the PECVD is a low frequency (LF) PECVD.

In an example embodiment, the annealing is performed for at least twenty four hours.

In an example embodiment, the annealing is performed for at least ninety hours.

In an example embodiment, the waveguide further comprises a cladding deposited on the low loss silicon nitride film.

In an example embodiment, waveguide is formed on a substrate and the substrate further comprising at least one of (a) one or more electrical circuit components or (b) one or more optical circuit components.

In an example embodiment, the at least one of (a) one or more electrical circuit components or (b) one or more optical circuit components was formed on the substrate prior to at least one of (i) the depositing of a silicon nitride film on the substrate or (ii) an annealing of the silicon nitride film to form the low loss silicon nitride film.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 provides a block diagram of an example trapped ion quantum computer comprising a waveguide comprising a low loss silicon nitride waveguide core, in accordance with an example embodiment.

FIGS. 2A and 2B each illustrate an example waveguide comprising a low loss silicon nitride waveguide core, in accordance with example embodiments.

FIG. 2C illustrates a cross-section of the example waveguide shown in FIG. 2A taken at the CC line, in accordance with an example embodiment.

FIG. 3A provides a flowchart illustrating various processes, procedures, and/or operations for fabricating a low loss silicon nitride film and/or waveguide core comprising low loss silicon nitride, in accordance with various embodiments.

FIG. 3B provides a flowchart illustrating various processes, procedures, and/or operations for fabricating a waveguide comprising a low loss silicon nitride core and/or photonic integrated circuit comprising a waveguide comprising a low loss silicon nitride core, in accordance with various embodiments.

FIG. 4 provides a schematic diagram of an example controller of a quantum computer comprising an ion trap apparatus, in accordance with an example embodiment.

FIG. 5 provides a schematic diagram of an example computing entity of a quantum computer system that may be used in accordance with an example embodiment.

### DETAILED DESCRIPTION OF SOME EXAMPLE EMBODIMENTS

The present invention now will be described more fully hereinafter with reference to the accompanying drawings, in which some, but not all embodiments of the invention are shown. Indeed, the invention may be embodied in many different forms and should not be construed as limited to the embodiments set forth herein; rather, these embodiments are provided so that this disclosure will satisfy applicable legal requirements. The term “or” (also denoted “/”) is used herein in both the alternative and conjunctive sense, unless otherwise indicated. The terms “illustrative” and “exemplary” are used to be examples with no indication of quality level. The terms “generally,” “substantially,” and “approximately” refer to within engineering and/or manufacturing limits and/or within user measurement capabilities, unless otherwise indicated. Like numbers refer to like elements throughout.

In various scenarios, optical signals are provided through waveguides. In general, the optical loss of a waveguide increases with decreasing wavelength. For example, ultraviolet light tends to experience greater losses when traveling through a waveguide than visible or infrared light. However, in various scenarios it is desired to provide high power ultraviolet and visible light to a target location where the light source is not able to directly provide the light to the target location. In such scenarios, waveguides may be used to provide the light generated by the light source to the target location (and possibly to one or more optical elements such as modulators, filters, and/or the like configured to condition the light). The high optical loss of waveguides exhibited at shorter wavelengths necessitates that the optical power of the initial beam provided by the light source is substantially greater than the optical power required at the target location. This results in very high energy consumption and waveguide damage. Therefore, technical problems exist regarding how to provide short wavelength optical beams (e.g., ultraviolet, light on the blue half of the visible spectrum, and/or the like) to target locations.

Various embodiments provide technical solutions to such technical problems. For example, various embodiments provide a low loss silicon nitride film (e.g., a low photonic loss silicon nitride film) that exhibits optical losses of 1 dB per centimeter or less. Various embodiments provide waveguide cores comprising low loss silicon nitride film, waveguide comprising waveguide cores comprising low loss silicon nitride film, integrated photonic circuits comprising waveguide comprising waveguide cores comprising low loss silicon nitride film, and/or the like. The low optical losses exhibited by the low loss silicon nitride film results in lower initial power requirements for optical beams provided to a target location through the low loss silicon nitride film (as part of a waveguide core, for example). Thus, various embodiments provide technical improvements to the technical field of waveguides for guiding ultraviolet and/or visible beams, for example. In various embodiments, the low loss silicon nitride is used to form improved gratings and/or other optical components. These improvements include reduced optical power loss, lower power consumption, and reduced waveguide damage.

Example Quantum Computer Comprising Waveguide with Low Loss Silicon Nitride Waveguide Core

Waveguides are used in a variety of contexts and/or scenarios. For example, the contexts and/or scenarios in which one may wish to guide light from one location to another location are numerous and varied. Various embodiments may be used to provide light guiding tools (e.g., waveguides and/or the like) with reduced optical power loss in a wide range of such contexts and/or scenarios.

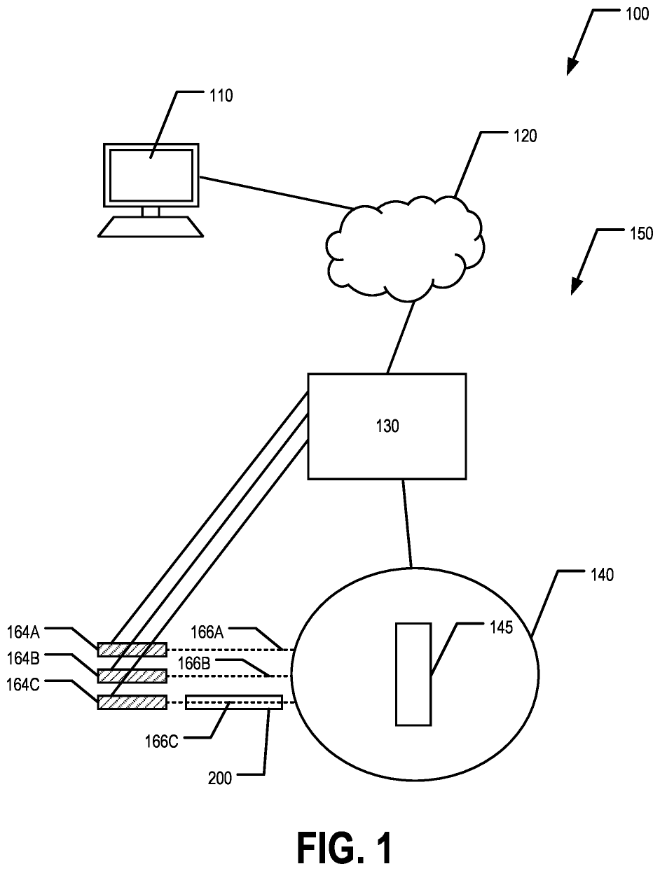

One example context is various quantum computing systems. One such example quantum computing system comprises a quantum charge-coupled device (QCCD)-based quantum computer. FIG. 1 provides a schematic diagram of an example quantum computer system 100 comprising at least one optical path 166 (166A, 166B, 166C) that is defined at least in part by a waveguide 200 having waveguide core comprising low loss silicon nitride. In various embodiments, the quantum computer system 100 comprises a computing entity 110 and a quantum computer 150. In various embodiments, the quantum computer 150 comprises a controller 130, a cryogenic and/or vacuum chamber 140 enclosing an ion trap 145, and one or more manipulation sources 164 (e.g., 164A, 164B, 164C). In an example embodiment, the one or more manipulation sources 164 may comprise one or more lasers (e.g., UV lasers, visible lasers, microwave lasers, and/or the like). In various embodiments, the one or more manipulation sources 164 are configured to manipulate and/or cause a controlled quantum state evolution of one or more ions within the ion trap 145. For example, in an example embodiment, wherein the one or more manipulation sources 164 comprise one or more lasers, the lasers may provide one or more laser beams to the ion trap 145 within the cryogenic and/or vacuum chamber 140. The one or more manipulation sources 164 each provide a laser beam and/or the like to the ion trap 145 via a corresponding optical paths 166 (e.g., 166A, 166B, 166C). In various embodiments, at least one optical path 166 comprises a waveguide 200 comprising a waveguide core formed of and/or comprising low loss silicon nitride. Via the waveguide 200 a manipulation source 164 may provide a modulated beam, via an optical path 166, to the ion trap 145.

In various embodiments, a computing entity 110 is configured to allow a user to provide input to the quantum computer 150 (e.g., via a user interface of the computing entity 110) and receive, view, and/or the like output from the quantum computer 150. The computing entity 110 may be in communication with the controller 130 of the quantum computer 150 via one or more wired or wireless networks 120 and/or via direct wired and/or wireless communications. In an example embodiment, the computing entity 110 may translate, configure, format, and/or the like information/data, quantum computing algorithms, and/or the like into a computing language, executable instructions, command sets, and/or the like that the controller 130 can understand and/or implement.

In various embodiments, the controller 130 is configured to control the electrical signal sources and/or drivers, cryogenic system and/or vacuum system controlling the temperature and pressure within the cryogenic and/or vacuum chamber 140, manipulation sources 164, and/or other systems controlling the environmental conditions (e.g., temperature, humidity, pressure, and/or the like) within the cryogenic and/or vacuum chamber 140 and/or configured to manipulate and/or cause a controlled evolution of quantum states of one or more ions within the ion trap 145. In various embodiments, the ions trapped within the ion trap 145 are used as qubits of the quantum computer 150.

### Example Low Loss Silicon Nitride Film and Components Comprising Same

In various embodiments, a low loss silicon nitride is provided. The low loss silicon nitride is used to form a waveguide core, in various embodiments. For example, in various embodiments, the low loss silicon nitride is used to form the waveguide core of a waveguide. In various embodiments, the low loss silicon nitride is used to form the waveguide core of at least a portion of a waveguide that is part of an integrated photonic circuit and/or formed on a substrate comprising other electrical and/or optical elements (e.g., conductive traces, resistors, capacitors, inductors, transistors, diodes, optical and/or electrical modulators, mirrors, lenses, prisms, gratings, and/or the like).

In various embodiments, the low loss silicon nitride is formed by depositing a silicon nitride film using, for example, chemical vapor deposition. In various embodiments, the low loss silicon nitride is formed by depositing a silicon nitride film using plasma enhanced chemical vapor deposition (PECVD). For example, the chemical vapor deposition may be performed at a temperature of less than 400° C. In various embodiments, the low loss silicon nitride is formed by depositing a silicon nitride film using a PECVD process that includes at least some low frequency (LF) power.

In various embodiments, the thickness of the silicon nitride film is 10 to 1000 nanometers. In an example embodiment, the thickness of the silicon nitride film is 10 to 500 nanometers.

In various embodiments, the silicon nitride film is annealed for at least ten hours at a temperature of at least 400° C. In various embodiments, the silicon nitride film is annealed for at least twenty-four hours at a temperature of at least 400° C. In various embodiments, the silicon nitride film is annealed for at least ninety hours at a temperature of at least 400° C. In various embodiments, the silicon nitride film is annealed for a time in a range of ten hours to two hundred hours at a temperature of at least 400° C. In an example embodiment, the annealing temperature is in a range of 400° C. to 1100° C.

In an example embodiment, the annealing process is performed in the presence of one or more active gases. For example, the silicon nitride film may be in the presence of Hydrogen, NH₃, and/or one or more other gasses during the annealing process. In various embodiments, the annealing process is performed in the presence of one or more inert gasses (instead of and/or in addition to the one or more active gasses).

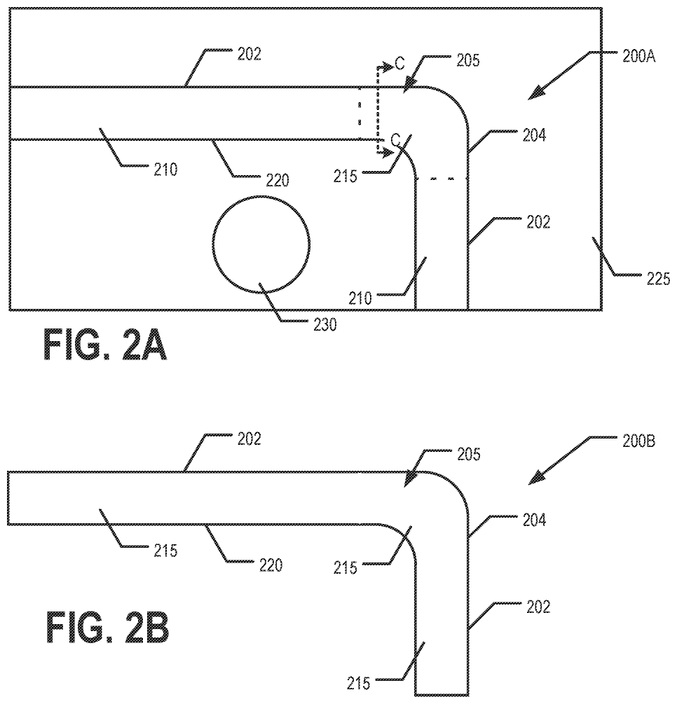

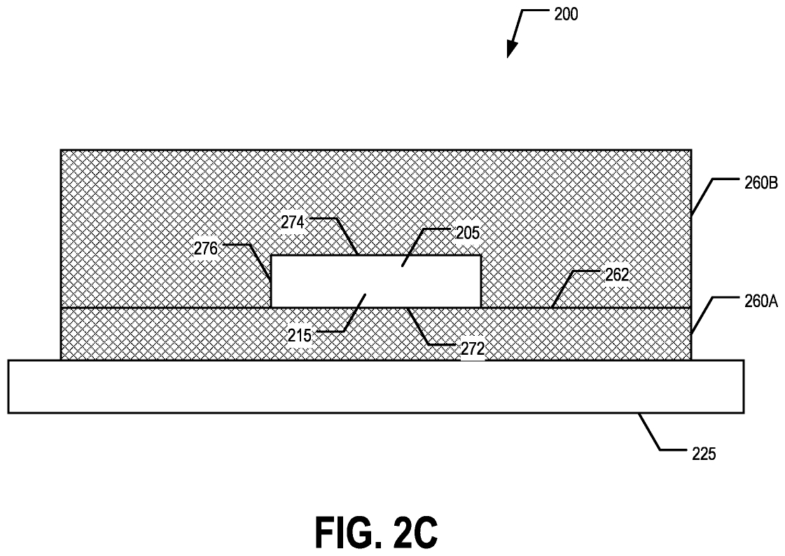

FIG. 2A illustrates an example waveguide 200A comprising a waveguide core 205 that comprises low loss silicon nitride 215. The example waveguide 200A comprises straight portions 202 and curved portion 204. The waveguide core of the curved portion 204 is formed of and/or comprises low loss silicon nitride 215. The waveguide core of the straight portions 210 comprise another waveguide core material (e.g., alumina and/or the like). In the illustrated embodiment, the waveguide core 205 of the waveguide 200A is formed on a substrate 225 and is at last partially enclosed by cladding 220. One or more optical and/or electrical elements 230 are also formed on the substrate. In various embodiments, one or more optical and/or electrical elements 230 are formed on the substrate before and/or after the silicon nitride film used to fabricate the low loss silicon nitride 215 is deposited on the substrate 225. In various embodiments, the substrate 225 is a silicon substrate or other substrate/wafer appropriate for the application.

FIG. 2B illustrates another example waveguide 200 comprising a waveguide core 205 that comprises low loss silicon nitride 215. The example waveguide 200B comprises straight portions 202 and curved portion 204. The waveguide core 205 of both the straight portions 202 and the curved portion 204 comprise and/or are formed of low loss silicon nitride 215. The waveguide core is at least partially enclosed by a cladding 220. Thought not shown, the waveguide 200B may be formed on a substrate 225. One or more optical and/or electrical elements 230 may also be formed on the substrate 225. For example, one or more optical and/or electrical elements 230 may be formed on the substrate 225 before and/or after the silicon nitride film used to fabricate the low loss silicon nitride 215 is deposited on the substrate 225. In various embodiments, the substrate 225 may be a silicon substrate or other substrate/wafer appropriate for the application.

FIG. 2C illustrates a cross-section of a waveguide 200 comprising a waveguide core 205 that comprises low loss silicon nitride 215 taken at line CC shown in FIG. 2A. A first cladding 260A is formed on the substrate 225 and the waveguide core 205 comprising low loss silicon nitride 215 is embedded between the first cladding 260A and the second cladding 260B. In various embodiments, the first cladding 260A and/or second cladding 260B comprises Tetraethyl orthosilicate (TEOS) and/or another material configured to optically and/or electrically isolate the waveguide core 205 from its surroundings. In various embodiments, the first cladding 260A and/or second cladding 260B extends ten to a few hundred microns away from the waveguide core 205 within the plane of FIG. 2C.

### Example Method of Fabricating Low Loss Silicon Nitride Film and Components Comprising Same

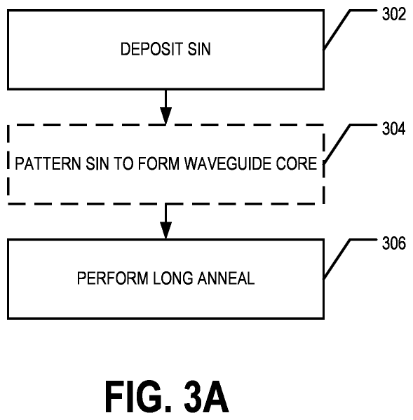

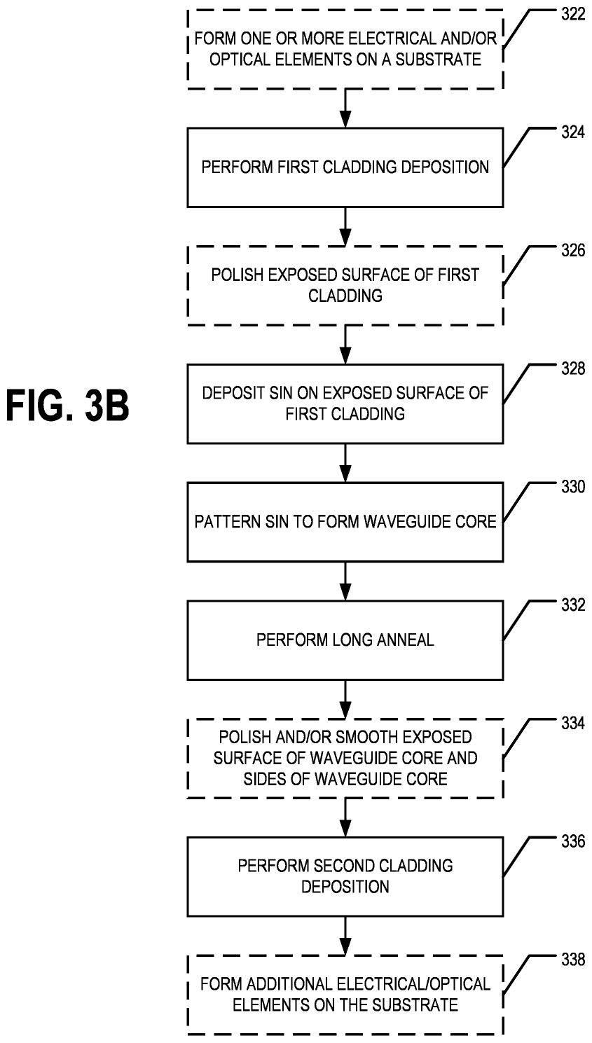

FIG. 3A provides a flowchart illustrating various processes, procedures, and/or the like for fabricating low loss silicon nitride (e.g., a low loss silicon nitride film) and/or a waveguide core comprising low loss silicon nitride.

Starting at step/operation 302, silicon nitride is deposited on a substrate, wafer, and/or the like. For example, a silicon nitride film is deposited on the substrate. In various embodiments, the silicon nitride is deposited on the substrate using chemical vapor deposition. In various embodiments, the silicon nitride is deposited on the substrate using PECVD. For example, the chemical vapor deposition may be performed at a temperature of less than 400° C. In various embodiments, the silicon nitride is deposited on the substrate using a PECVD process that includes the use of at least some LF power. In an example embodiment, the silicon nitride is deposited on the substrate using a PECVD process that includes the use of a combination of LF power and high frequency power. In an example embodiment, the silicon nitride is deposited on the substrate using an LF PECVD process.

At optional step/operation 304, in an example embodiment where a waveguide core is being formed, the silicon nitride is patterned to form the desired waveguide core. For example, a waveguide core appropriate for the application may be patterned from the deposited silicon nitride.

At step/operation 306, a long anneal process is performed to transform and/or convert the silicon nitride into low loss silicon nitride. For example, the long anneal process causes the silicon nitride to become low loss silicon nitride. In various embodiments, a long anneal process includes annealing the silicon nitride (e.g., the substrate and any element formed on the substrate) for at least ten hours at a temperature of at least 400° C. In various embodiments, a long anneal process includes annealing the silicon nitride (e.g., the substrate and any element formed on the substrate) for at least twenty-four hours at a temperature of at least 400° C. In various embodiments, a long anneal process includes annealing the silicon nitride (e.g., the substrate and any element formed on the substrate) for at least ninety hours at a temperature of at least 400° C. In various embodiments, a long anneal process includes annealing the silicon nitride (e.g., the substrate and any element formed on the substrate) for a time in a range of ten hours to two hundred hours at a temperature of at least 400° C. In an example embodiment, the annealing temperature is in a range of 400° C. to 1100° C.

In an example embodiment, the annealing process is performed in the presence of one or more active gases. For example, the silicon nitride film may be in the presence of Hydrogen, NH₃, and/or one or more other gasses during the annealing process. In various embodiments, the annealing process is performed in the presence of one or more inert gasses (instead of and/or in addition to the one or more active gasses).

In an example embodiment, the low loss silicon nitride film is formed as part of a waveguide (e.g., the waveguide core) of a waveguide and/or photonic integrated circuit (PIC). For example, the silicon nitride may be deposited on a substrate (and/or first cladding formed on the first substrate) and a waveguide and/or PIC including the silicon nitride is formed on the first substrate. In an example embodiment, the low loss film is prepared on a first substrate and then bonded and/or transferred onto a second substrate (e.g., onto a first cladding formed on the second substrate).

FIG. 3B provides a flowchart illustrating various processes, procedures, and/or the like for fabricating a waveguide comprising a waveguide core comprising low loss silicon nitride (e.g., a low loss silicon nitride film) and/or optical/PIC comprising a low loss silicon nitride film and/or waveguide core.

Starting at optional step/operation 322, one or more electrical and/or optical elements are formed on a substrate. For example, one or more conductive traces, resistors, capacitors, inductors, transistors, diodes, optical and/or electrical modulators, mirrors, lenses, prisms, gratings, and/or other electrical and/or optical elements may be formed on the substrate, as appropriate for the application.

At step 324, a first cladding deposition is performed. For example, a first cladding 260A is deposited on the substrate 225. In various embodiments, the first cladding 260A and/or second cladding 260B comprises TEOS and/or another material configured to optically and/or electrically isolate the waveguide core 205 from its surroundings. In an example embodiment, the first cladding is deposited using a PECVD process.

At optional step 326, a polishing step is performed to smooth and/or clean the exposed surface 262 of the first cladding 260A. For example, a chemical mechanical polishing process may be performed on the exposed surface 262 of the first cladding 260A.

At step/operation 328, silicon nitride is deposited on a substrate, wafer, and/or the like. For example, a silicon nitride film is deposited on the substrate. In various embodiments, the silicon nitride is deposited on the substrate using chemical vapor deposition. In various embodiments, the silicon nitride is deposited on the substrate using PECVD. For example, the chemical vapor deposition may be performed at a temperature of less than 400° C. In various embodiments, the silicon nitride is deposited on the substrate using a PECVD process that includes the use of at least some LF power. In an example embodiment, the silicon nitride is deposited on the substrate using a PECVD process that includes the use of a combination of LF power and high frequency power. In an example embodiment, the silicon nitride is deposited on the substrate using an LF PECVD process. For example, a first surface 272 of the silicon nitride may be formed on the exposed surface 262 of the first cladding 260A, in an example embodiment.

At step/operation 330, in an example embodiment where a waveguide core is being formed, the silicon nitride is patterned to form the desired waveguide core. For example, a waveguide core appropriate for the application may be patterned from the deposited silicon nitride.

At step/operation 332, a long anneal process is performed to transform and/or convert the silicon nitride into low loss silicon nitride. For example, the long anneal process causes the silicon nitride to become low loss silicon nitride. In various embodiments, a long anneal process includes annealing the silicon nitride (e.g., the substrate and any element formed on the substrate) for at least ten hours at a temperature of at least 400° C. In various embodiments, a long anneal process includes annealing the silicon nitride (e.g., the substrate and any element formed on the substrate) for at least twenty-four hours at a temperature of at least 400° C. In various embodiments, a long anneal process includes annealing the silicon nitride (e.g., the substrate and any element formed on the substrate) for at least ninety hours at a temperature of at least 400° C. In various embodiments, a long anneal process includes annealing the silicon nitride (e.g., the substrate and any element formed on the substrate) for a time in a range of ten hours to two hundred hours at a temperature of at least 400° C. In an example embodiment, the annealing temperature is in a range of 400° C. to 1100° C.

In an example embodiment, the annealing process is performed in the presence of one or more active gases. For example, the silicon nitride film may be in the presence of Hydrogen, NH₃, and/or one or more other gasses during the annealing process. In various embodiments, the annealing process is performed in the presence of one or more inert gasses (instead of and/or in addition to the one or more active gasses).

At optional step 334, the exposed surface 274 of the waveguide core 205 and/or the sides 276 of the waveguide core 206 are smoothed, polished, and/or cleaned. For example, a chemical mechanical polishing process and/or other process configured to reduce the roughness of the exposed surface 274 of the waveguide core 205 and/or the sides 276 of the waveguide core 206 may be performed on the exposed surface 274 of the waveguide core 205 and/or the sides 276 of the waveguide core 206.

At optional step/operation 336, a second cladding deposition is performed. For example, a second cladding 260B is deposited on the exposed surface 274 of the waveguide core 205 and the exposed surface 262 of the first cladding 260A which is not covered by the waveguide core 205. In various embodiments, the first cladding 260A and/or second cladding 260B comprises TEOS and/or another material configured to optically and/or electrically isolate the waveguide core 205 from its surroundings. In an example embodiment, the first cladding is deposited using a PECVD process. In various embodiments, the second cladding is deposited such that the first cladding and the second cladding enclose the low loss silicon nitride and/or waveguide core patterned from the silicon nitride/low loss silicon nitride.

At optional step/operation 338, one or more additional electrical and/or optical elements are formed on a substrate. For example, one or more additional conductive traces, resistors, capacitors, inductors, transistors, diodes, optical and/or electrical modulators, mirrors, lenses, prisms, gratings, and/or other electrical and/or optical elements may be formed on the substrate, as appropriate for the application.

As should be understood, various steps/operations may be performed in different orders than illustrated in various embodiments. For example, in an example embodiment, the waveguide core is patterned after the long annealing is performed. In another example, in an example embodiment, the cladding is formed prior to the performance of the long annealing process. Various other steps/operations may be added to those illustrated in FIGS. 3A and/or 3B and/or modified to fabricate a desired component comprising low loss silicon nitride.

### Example Controller

In various embodiments, a waveguide 200 having a waveguide core comprising low loss silicon nitride is incorporated into a quantum computer 150. In various embodiments, a quantum computer 150 further comprises a controller 130 configured to control various elements of the quantum computer 150. For example, the controller 130 may be configured to control the voltage sources and/or drivers configured to provide electrical signal(s) to control the modulation of one or more beams via corresponding modulator(s), a cryogenic system and/or vacuum system controlling the temperature and pressure within the cryogenic and/or vacuum chamber 140, manipulation sources 164, and/or other systems controlling the environmental conditions (e.g., temperature, humidity, pressure, and/or the like) within the cryogenic and/or vacuum chamber 140 and/or configured to manipulate and/or cause a controlled evolution of quantum states of one or more ions within the ion trap 145.

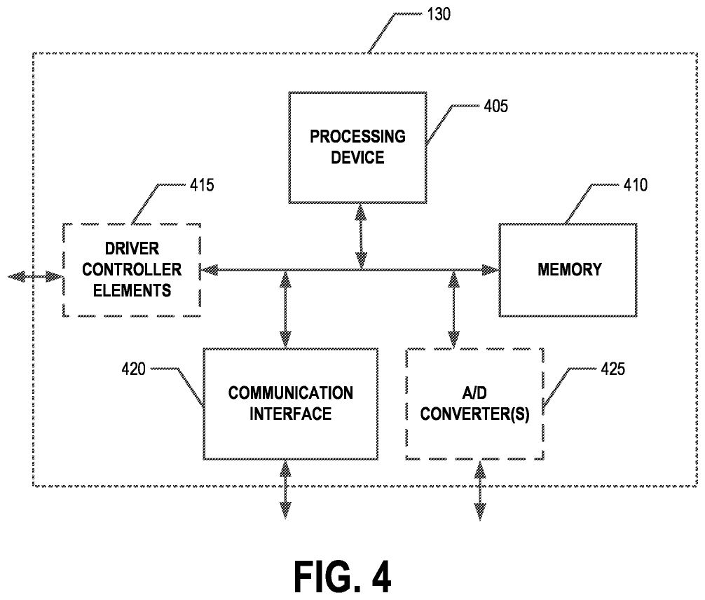

As shown in FIG. 4, in various embodiments, the controller 130 may comprise various controller elements including processing device 405, memory 410, driver controller elements 415, a communication interface 420, analog-digital converter elements 425, and/or the like. For example, the processing device 405 may comprise processing elements, programmable logic devices (CPLDs), microprocessors, coprocessing entities, application-specific instruction-set processors (ASIPs), integrated circuits, application specific integrated circuits (ASICs), field programmable gate arrays (FPGAs), programmable logic arrays (PLAs), hardware accelerators, other processing devices and/or circuitry, and/or the like. and/or controllers. The term circuitry may refer to an entirely hardware embodiment or a combination of hardware and computer program products. In an example embodiment, the processing device 405 of the controller 130 comprises a clock and/or is in communication with a clock.

For example, the memory 410 may comprise non-transitory memory such as volatile and/or non-volatile memory storage such as one or more of as hard disks, ROM, PROM, EPROM, EEPROM, flash memory, MMCs, SD memory cards, Memory Sticks, CBRAM, PRAM, FeRAM, RRAM, SONOS, racetrack memory, RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. In various embodiments, the memory 410 may store qubit records corresponding the qubits of quantum computer (e.g., in a qubit record data store, qubit record database, qubit record table, and/or the like), a calibration table, an executable queue, computer program code (e.g., in a one or more computer languages, specialized controller language(s), and/or the like), and/or the like. In an example embodiment, execution of at least a portion of the computer program code stored in the memory 410 (e.g., by a processing device 405) causes the controller 130 to perform one or more steps, operations, processes, procedures and/or the like described herein for tracking the phase of an atomic object within an atomic system and causing the adjustment of the phase of one or more manipulation sources and/or signal(s) generated thereby.

In various embodiments, the driver controller elements 415 may include one or more drivers and/or controller elements each configured to control one or more drivers. In various embodiments, the driver controller elements 415 may comprise drivers and/or driver controllers. For example, the driver controllers may be configured to cause one or more corresponding drivers to be operated in accordance with executable instructions, commands, and/or the like scheduled and executed by the controller 130 (e.g., by the processing device 405). In various embodiments, the driver controller elements 415 may enable the controller 130 to operate a manipulation source 164. In various embodiments, the drivers may be laser drivers; vacuum component drivers; drivers for controlling the flow of current and/or voltage of an electrical signal applied to electrodes of an ion trap 145; cryogenic and/or vacuum system component drivers; and/or the like. In various embodiments, the controller 130 comprises means for communicating and/or receiving signals from one or more optical receiver components such as cameras, MEMS cameras, CCD cameras, photodiodes, photomultiplier tubes, and/or the like. For example, the controller 130 may comprise one or more analog-digital converter elements 425 configured to receive signals from one or more optical receiver components, calibration sensors, and/or the like.

In various embodiments, the controller 130 may comprise a communication interface 420 for interfacing and/or communicating with a computing entity 110. For example, the controller 130 may comprise a communication interface 420 for receiving executable instructions, command sets, and/or the like from the computing entity 110 and providing output received from the quantum computer 150 (e.g., from an optical collection system) and/or the result of a processing the output to the computing entity 110. In various embodiments, the computing entity 110 and the controller 130 may communicate via a direct wired and/or wireless connection and/or one or more wired and/or wireless networks 120.

### Example Computing Entity

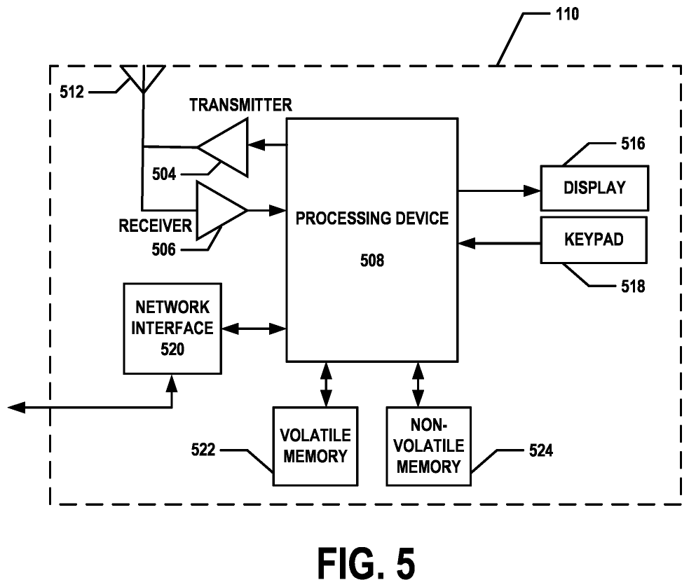

FIG. 5 provides an illustrative schematic representative of an example computing entity 110 that can be used in conjunction with embodiments of the present invention. In various embodiments, a computing entity 110 is configured to allow a user to provide input to the quantum computer 150 (e.g., via a user interface of the computing entity 110) and receive, display, analyze, and/or the like output from the quantum computer 150.

As shown in FIG. 5, a computing entity 110 can include an antenna 512, a transmitter 504 (e.g., radio transmitter), a receiver 506 (e.g., radio receiver), and a processing device 508 that provides signals to and receives signals from the transmitter 504 and receiver 506, respectively. The signals provided to and received from the transmitter 504 and the receiver 506, respectively, may include signaling information/data in accordance with an air interface standard of applicable wireless systems to communicate with various entities, such as a controller 130, other computing entities 110, and/or the like. In this regard, the computing entity 110 may be capable of operating with one or more air interface standards, communication protocols, modulation types, and access types. For example, the computing entity 110 may be configured to receive and/or provide communications using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing entity 110 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1× (1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol. The computing entity 110 may use such protocols and standards to communicate using Border Gateway Protocol (BGP), Dynamic Host Configuration Protocol (DHCP), Domain Name System (DNS), File Transfer Protocol (FTP), Hypertext Transfer Protocol (HTTP), HTTP over TLS/SSL/Secure, Internet Message Access Protocol (IMAP), Network Time Protocol (NTP), Simple Mail Transfer Protocol (SMTP), Telnet, Transport Layer Security (TLS), Secure Sockets Layer (SSL), Internet Protocol (IP), Transmission Control Protocol (TCP), User Datagram Protocol (UDP), Datagram Congestion Control Protocol (DCCP), Stream Control Transmission Protocol (SCTP), HyperText Markup Language (HTML), and/or the like.

Via these communication standards and protocols, the computing entity 110 can communicate with various other entities using concepts such as Unstructured Supplementary Service information/data (USSD), Short Message Service (SMS), Multimedia Messaging Service (MMS), Dual-Tone Multi-Frequency Signaling (DTMF), and/or Subscriber Identity Module Dialer (SIM dialer). The computing entity 110 can also download changes, add-ons, and updates, for instance, to its firmware, software (e.g., including executable instructions, applications, program modules), and operating system.

The computing entity 110 may also comprise a user interface device comprising one or more user input/output interfaces (e.g., a display 516 and/or speaker/speaker driver coupled to a processing device 508 and a touch screen, keyboard, mouse, and/or microphone coupled to a processing device 508). For instance, the user output interface may be configured to provide an application, browser, user interface, interface, dashboard, screen, webpage, page, and/or similar words used herein interchangeably executing on and/or accessible via the computing entity 110 to cause display or audible presentation of information/data and for interaction therewith via one or more user input interfaces. The user input interface can comprise any of a number of devices allowing the computing entity 110 to receive data, such as a keypad 518 (hard or soft), a touch display, voice/speech or motion interfaces, scanners, readers, or other input device. In embodiments including a keypad 518, the keypad 518 can include (or cause display of) the conventional numeric (0-9) and related keys (#, *), and other keys used for operating the computing entity 110 and may include a full set of alphabetic keys or set of keys that may be activated to provide a full set of alphanumeric keys. In addition to providing input, the user input interface can be used, for example, to activate or deactivate certain functions, such as screen savers and/or sleep modes. Through such inputs the computing entity 110 can collect information/data, user interaction/input, and/or the like.

The computing entity 110 can also include volatile storage or memory 522 and/or non-volatile storage or memory 524, which can be embedded and/or may be removable. For instance, the non-volatile memory may be ROM, PROM, EPROM, EEPROM, flash memory, MMCs, SD memory cards, Memory Sticks, CBRAM, PRAM, FeRAM, RRAM, SONOS, racetrack memory, and/or the like. The volatile memory may be RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. The volatile and non-volatile storage or memory can store databases, database instances, database management system entities, data, applications, programs, program modules, scripts, source code, object code, byte code, compiled code, interpreted code, machine code, executable instructions, and/or the like to implement the functions of the computing entity 110.

### CONCLUSION

Many modifications and other embodiments of the invention set forth herein will come to mind to one skilled in the art to which the invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A method for forming a low loss silicon nitride film, the method comprising:
depositing a silicon nitride film on a substrate; and
annealing the silicon nitride film for at least ten hours at a temperature of at least 400° C. to cause the silicon nitride film to become a low loss silicon nitride film,
wherein the low loss silicon nitride film has an optical loss of less than 1 dB per cm at a wavelength of 488 nm.

2. The method of claim 1, wherein the silicon nitride film is formed using chemical vapor deposition.

3. The method of claim 2, wherein the chemical vapor deposition is a plasma enhanced chemical vapor deposition (PECVD).

4. The method of claim 3, wherein the PECVD comprises the use of at least some low frequency (LF) power.

5. The method of claim 1, wherein the annealing is performed for at least twenty four hours.

6. The method of claim 1, wherein the annealing is performed for at least ninety hours.

7. The method of claim 1, further comprising at least one of (a) before depositing the silicon nitride film or (b) after depositing the silicon nitride film, forming at least one of (i) one or more electrical circuit components or (ii) optical circuit components on the substrate.

8. The method of claim 1, further comprising patterning the low loss silicon nitride film into a waveguide core.

9. The method of claim 8, further comprising depositing a cladding on the low loss silicon nitride film.

10. The method of claim 8, wherein the waveguide core is a core of a waveguide configured for guiding at least one of visible or ultraviolet light.

11. A waveguide for guiding visible and/or ultraviolet light, the waveguide comprising:
a low loss silicon nitride waveguide core, wherein the low loss silicon nitride waveguide core is formed by annealing a silicon nitride film for at least ten hours at a temperature of at least 400° C.

12. The waveguide of claim 11, wherein the waveguide has an optical loss of less than 3 dB per cm at a wavelength of 488 nm.

13. The waveguide of claim 12, wherein the silicon nitride film was formed by depositing the silicon nitride film on a substrate using chemical vapor deposition.

14. The waveguide of claim 13, wherein the chemical vapor deposition is a plasma enhanced chemical vapor deposition (PECVD).

15. The waveguide of claim 14, wherein the PECVD comprises the use of at least some low frequency (LF) power.

16. The waveguide of claim 12, wherein the annealing is performed for at least twenty four hours.

17. The waveguide of claim 12, wherein the annealing is performed for at least ninety hours.

18. The waveguide of claim 11, further comprising a cladding enclosing the low loss silicon nitride film in directions radial to a propagation direction defined by the waveguide core.

19. The waveguide of claim 11, wherein the waveguide is formed on a substrate and the substrate further comprising at least one of (a) one or more electrical circuit components or (b) one or more optical circuit components.

20. The waveguide of claim 19, wherein the at least one of (a) one or more electrical circuit components or (b) one or more optical circuit components was formed on the substrate prior to at least one of (i) the depositing of a silicon nitride film on the substrate or (ii) an annealing of the silicon nitride film to form the low loss silicon nitride film.
